(19) United States
(12) Patent Application Publication
(10) Pub. No.: US 2022/0149174 A1
(43) Pub. Date: May 12, 2022

(54) SEMICONDUCTOR DEVICE AND METHOD FOR MANUFACTURING SEMICONDUCTOR DEVICE

(71) Applicant: KYOCERA Corporation, Kyoto-shi, Kyoto (JP)

(72) Inventor: Tatsuro SAWADA, Tsukuba-shi (JP)

(73) Assignee: KYOCERA Corporation, Kyoto-shi, Kyoto (JP)

(21) Appl. No.: 17/599,498

(22) PCT Filed: Mar. 26, 2020
(86) PCT No.: PCT/JP2020/013680

§ 371 Date: Sep. 28, 2021

(30) Foreign Application Priority Data
Mar. 29, 2019 (JP) 2019-065351

(51) Int. Cl. H01L 29/47; H01L 21/306; H01L 29/40; H01L 29/872

(52) U.S. Cl. CPC H01L 29/47; H01L 29/872; H01L 29/401; H01L 21/30608

(57) ABSTRACT

A semiconductor device includes: a semiconductor substrate; a semiconductor layer of a first conductivity type that is deposited on a surface of the semiconductor substrate; a trench that is formed on a surface of the semiconductor layer; an insulating film that covers a bottom surface of the trench and a lateral surface of the trench; a conductive body that fills inside the trench that is covered by the insulating film; a second conductive type region that is formed in the semiconductor layer, is arranged under the trench, and is within a region of the trench in a plan view of the semiconductor substrate; and a metal film that is electrically connected to the conductive body and forms a Schottky barrier with the surface of the semiconductor layer.

### TECHNICAL FIELD

The present disclosure relates to a semiconductor device such as a diode and a transistor having a trench structure, and a method for manufacturing the semiconductor device.

### BACKGROUND ART

Conventionally, as described in JP 2016-502270A, there has been known a semiconductor device having a trench structure in which a trench is formed in a semiconductor layer having a first conductivity type that forms a Schottky barrier, and a low-concentration region of a second conductivity type is formed in the semiconductor layer disposed at a bottom portion of the trench.

### SUMMARY OF INVENTION

### Technical Problem

In the conventional semiconductor device described above, in a plan view of the semiconductor substrate, the low-concentration region of the second conductivity type protrudes out of the trench.

In such a structure where the low-concentration region of the second conductivity type protrudes outward from the bottom portion of the trench, the low-concentration region of the second conductivity type protrudes in a conductive region for forward current. This causes an increase in on-resistance and degradation of the forward characteristics.

By forming the above low-concentration region of the second conductivity type to improve the voltage resistance, and further by forming the region larger, the voltage resistance can be improved, but at the same time the on-resistance will increase. It is difficult to improve the voltage resistance while suppressing the increase in on-resistance.

### Solution to Problem

According to one embodiment of the present disclosure, there is provided a semiconductor device including: a semiconductor substrate; a semiconductor layer of a first conductivity type that is deposited on a surface of the semiconductor substrate; a trench that is formed on a surface of the semiconductor layer; an insulating film that covers a bottom surface of the trench and a lateral surface of the trench; a conductive body that fills inside the trench that is covered by the insulating film; a second conductive type region that is formed in the semiconductor layer; and a metal film that is electrically connected to the conductive body and forms a Schottky barrier with a surface of the semiconductor layer, wherein the second conductive type region is arranged under the trench and is within a region of the trench in a plan view of the semiconductor substrate.

According to one embodiment of the present disclosure, there is provided a method for manufacturing a semiconductor device, the semiconductor device including: a semiconductor substrate; a semiconductor layer of a first conductivity type that is deposited on a surface of the semiconductor substrate; a trench that is formed on a surface of the semiconductor layer; an insulating film that covers a bottom surface of the trench and a lateral surface of the trench; a conductive body that fills inside the trench that is covered by the insulating film; a second conductive type region that is formed in the semiconductor layer; and a metal film that is electrically connected to the conductive body and forms a Schottky barrier with a surface of the semiconductor layer, and the second conductive type region being arranged under the trench, the method including: forming a doping mask that is an insulator mask pattern that exposes a middle portion of the bottom surface and that covers a surface of the semiconductor layer around the trench, an outer edge portion of a bottom surface of the trench, and a lateral surface of the trench; and doping an impurity of a second conductive type using the insulator mask pattern as a mask, including introducing the impurity in the semiconductor layer through the middle portion of the bottom surface.

### BRIEF DESCRIPTION OF DRAWINGS

FIG. 1 is a cross-sectional schematic diagram to illustrate a first embodiment of the present disclosure.

FIG. 2 is a cross-sectional schematic diagram to illustrate the first embodiment of the present disclosure.

FIG. 3 is a cross-sectional schematic diagram to illustrate the first embodiment of the present disclosure.

FIG. 4 is a cross-sectional schematic diagram to illustrate the first embodiment of the present disclosure.

FIG. 5 is a cross-sectional schematic diagram to illustrate the first embodiment of the present disclosure.

FIG. 6 is a cross-sectional schematic diagram to illustrate the first embodiment of the present disclosure.

FIG. 7 is a cross-sectional schematic diagram to illustrate the first embodiment of the present disclosure.

FIG. 8 is a cross-sectional schematic diagram to illustrate a second embodiment of the present disclosure.

FIG. 9 is a cross-sectional schematic diagram to illustrate the second embodiment of the present disclosure.

FIG. 10 is a cross-sectional schematic diagram to illustrate the second embodiment of the present disclosure.

FIG. 11 is a cross-sectional schematic diagram to illustrate the second embodiment of the present disclosure.

FIG. 12 is a cross-sectional schematic diagram to illustrate the second embodiment of the present disclosure.

FIG. 13 is a cross-sectional schematic diagram to illustrate the second embodiment of the present disclosure.

FIG. 14 is a cross-sectional schematic diagram to illustrate the second embodiment of the present disclosure.

FIG. 15 is a graph comparing examples of comparison and the present invention regarding a forward voltage and a voltage resistance.

### DESCRIPTION OF EMBODIMENTS

Hereinafter, an embodiment of the present disclosure will be explained with reference to the drawings.

### First Embodiment

First, a method for manufacturing a semiconductor device according to a first embodiment and the semiconductor device will be described.

### (Manufacturing Method)

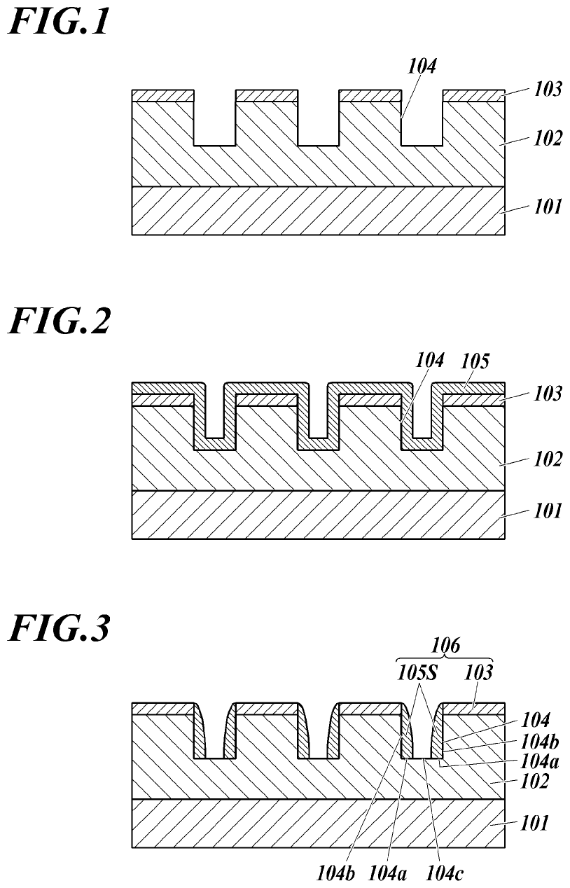

The semiconductor device is manufactured as follows. A process of forming a trench is performed as shown in FIG. 1. That is, an insulator mask pattern 103 for trench formation is formed on a semiconductor layer 102 on a semiconductor substrate 101, and a trench 104 is formed by etching using the insulator mask pattern 103 as a mask.

The semiconductor substrate 101 is an N-type high-concentration silicon substrate. The semiconductor layer 102 is an N-type low-concentration semiconductor layer deposited on the surface of the semiconductor substrate 101 by an epitaxial growth method.

The insulator mask pattern 103 is a mask pattern for etching that opens on a surface of the semiconductor layer 102 in a region where the trench is to be formed. An insulating material that constitutes the insulator mask pattern 103 includes silicon oxide, silicon nitride, TEOS (tetraethyl orthosilicate), or the like. The insulator mask pattern 103 is deposited by, for example, chemical vapor deposition (CVD)

Any number of trenches 104 can be formed.

The semiconductor substrate 101 and the semiconductor layer 102 may be one of the following semiconductor materials: SiC (silicon carbide), GaN (gallium nitride), or Ga₂O₃ (gallium oxide).

Next, a process of forming a doping mask is performed to introduce a P-type impurity under the trench 104, followed by a process of doping.

In the process of forming a doping mask, first, an insulator layer 105 is formed as shown in FIG. 2. The insulator layer 105 is deposited on the insulator mask pattern 103 described in the above process of forming the trench. At the same time, the insulator layer 105 covers the bottom surface and lateral surface of the trench 104. An insulating material that constitutes the insulator layer 105 includes silicon oxide, silicon nitride, TEOS (tetraethyl orthosilicate), or the like. The insulator layer 105 is deposited by using, for example, chemical vapor deposition (CVD).

Next, as shown in FIG. 3, the entire surface is etched. The etching applied is anisotropic etching. As the anisotropic etching, a reactive etching method is applied in which the etching rate in the vertical direction, perpendicular to the surface, is larger than the etching rate in the horizontal direction, parallel to the surface.

Therefore, as shown in FIG. 3, it is possible to expose a middle portion 104c of the bottom surface of the trench 104 while a sidewall insulator 105S is left, which is a part of the insulator layer 105 and covers the outer edge portion 104a of the bottom surface and the lateral surface 104b of the trench 104. This is because the sidewall insulator 105S remains when the insulator on the middle portion 104c of the bottom surface of the trench 104 is removed by vertical etching.

The sidewall insulator 105S is thicker at a portion closer to the bottom surface of the trench 104 because the etching progresses more at the portion closer to the opening of the trench 104.

On the surface of the semiconductor layer 102 around the trench 104, the insulator mask pattern 103 is covered by the insulator layer 105 before etching as shown in FIG. 2. Therefore, when the insulator on the middle portion 104c of the bottom surface of the trench 104 is removed by vertical etching, the insulator mask pattern 103 also remains.

The insulator mask pattern 103 and the sidewall insulator 105S remaining after the above anisotropic etching are collectively referred to as an insulator mask pattern 106.

As shown in FIG. 3, the insulator mask pattern 106 is a pattern that covers the surface of the semiconductor layer 102 around the trench 104, the outer edge portion 104a of the bottom surface of the trench 104, and the lateral surface 104b of the trench 104, and exposes the middle portion 104c of the same bottom surface. This insulator mask pattern 106 is used as a mask for the subsequent doping process.

Next, the process of doping is performed.

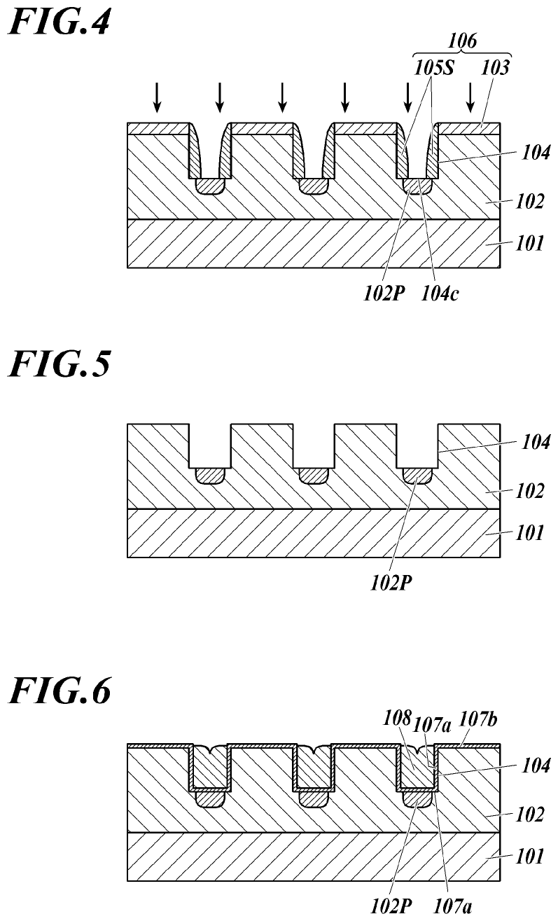

In the process of doping, as shown in FIG. 4, an impurity of a second conductivity type (P-type in this embodiment) is introduced into the semiconductor layer 102 through the middle portion 104c of the bottom surface of the trench 104, using the insulator mask pattern 106 as a mask. An ion implantation method is applied as the method for introducing impurity. Since there is a sidewall insulator 105S in the trench 104, ion implantation to the semiconductor layer 102 is limited to the middle portion 104c inside the sidewall insulator 105S.

After being introduced, the P-type impurity is activated by annealing to form a P-type region 102P. After this annealing, the P-type impurity diffuses in the semiconductor layer 102 more than at the time of ion implantation, but remains within the width of the trench 104 in the lateral direction, so that the P-type region 102P does not protrude outward from the trench 104.

Next, the insulator mask pattern 106 is removed as shown in FIG. 5, insulating films (thermal oxide films) 107a and 107b are formed on the surface of the semiconductor layer 102 including inside the trench 104 as shown in FIG. 6, and then the trench 104 is filled with a conductive body 108. The material of the conductive body 108 may be polysilicon or a metal material.

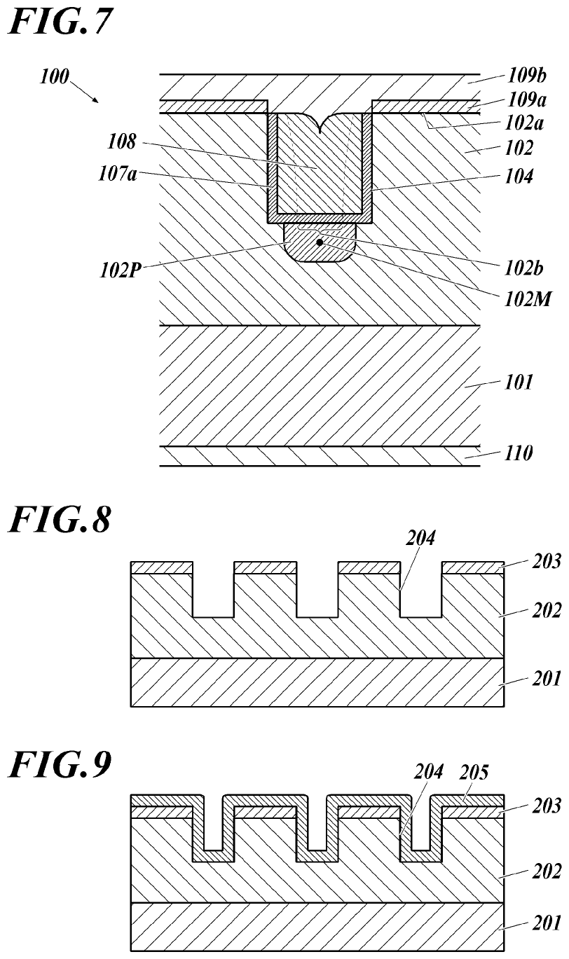

Furthermore, after the insulating film 107b around the trench 104 is removed, as shown in FIG. 7, a Schottky metal film 109a is joined with the surface 102a of the semiconductor layer 102 to form a Schottky barrier, and then a surface electrode metal film 109b is further formed to connect the Schottky metal film 109a and the conductive body 108. Furthermore, a back electrode metal film 110 is formed.

### (Semiconductor Device)

The semiconductor device 100 shown in FIG. 7 that can be manufactured by the above manufacturing method, for example, includes: the semiconductor substrate 101 that has a first conductivity type at a relatively high concentration; the semiconductor layer 102 that is deposited on the surface of the semiconductor substrate 101 and has the first conductivity type at a relatively low concentration; the trench 104 formed on the surface of the semiconductor layer 102; the insulating film 107a that covers the bottom surface and the lateral surface of the trench 104; the conductive body 108 that fills the inside of the trench 104 covered by the insulating film 107a; the second conductive type region 102P that is formed in the semiconductor layer 102; and the Schottky metal film 109a that electrically connects to the conductive body 108 and forms the Schottky barrier with the surface 102a of the semiconductor layer 102.

The second conductive type region 102P is arranged under the trench 104 and is within the region of the trench 104 in a plan view of the semiconductor substrate 101.

More specifically, in a plan view of the semiconductor substrate 101, the second conductive type region 102P is not in contact with the outer edge of the region of the trench 104 but is separated from the outer edge by a certain distance to be within the region of the trench 104.

The second conductive type region 102P is within the width of the bottom portion of the trench 104, and does not cover a corner at the bottom portion of the trench 104. The corner at the bottom portion of the trench 104 may have a round shape. This effectively relaxes local concentration of the electric field when a reverse voltage is applied.

The region in the semiconductor layer 102 except the region of the trench 104 in the plan view of the semiconductor substrate 101 is occupied by the first conductive type (N-type) region. Therefore, it is possible to ensure a large conductive region for forward current under a Schottky junction.

The second conductive type region 102P is a region formed by ion implantation. The ion implanted surface appearing at the bottom surface of the trench 104 corresponds to the middle portion 104c in FIG. 4. In a plan view of the semiconductor substrate 101, the middle portion 104c does not contact the outer edge of the region of the trench 104, but is inside the region of the trench 104. The ion implanted surface 102b appearing at the bottom surface of the trench 104 has a width narrower than the final diffusion width of the second conductive type region 102P in FIG. 7. The outline of the sidewall insulator 105S in FIG. 4 is also illustrated with dashed lines in FIG. 7. The inside of the lines corresponds to the ion implanted surface 102b.

The impurity concentration distribution of the second conductivity type (P-type) in the second conductive type region 102P takes its highest value at a depth separated from the bottom surface of the trench 104 (at a point 102M in FIG. 7). This is due to the ion implantation, and the formation of the peak at a deep position results in a good electrolytic relaxation effect.

The P-type impurity also diffuses laterally from the ion implanted surface 102b, but it is distributed at a lower concentration than at the ion implanted surface 102b.

The semiconductor device 100 can be applied to SBDs (Schottky diodes), MOSFETs (metal-oxide-semiconductor field-effect transistors), IGBTs (Insulated Gate Bipolar Transistors), and the like.

When the semiconductor device 100 constitutes a MOSFET, the P-body, gate, and the like are formed in the center portion, and the surface electrode metal film 109b serves as a source electrode and the back electrode metal film 110 serves as a drain electrode. When the semiconductor device 100 constitutes an IGBT, further, a p-type high-concentration substrate is applied as the semiconductor substrate 101, the surface electrode metal film 109b serves as an emitter electrode, and the back electrode metal film 110 serves as a collector electrode.

### Second Embodiment

Next, a method for manufacturing a semiconductor device according to a second embodiment and the semiconductor device will be described.

### (Manufacturing Method)

The semiconductor device is manufactured as follows. A process of forming a trench is carried out as shown in FIG. 8. That is, an insulator mask pattern 203 for trench formation is formed on a semiconductor layer 202 on a semiconductor device 201, and a trench 204 is formed by etching using the insulator mask pattern 203 as a mask.

The semiconductor substrate 201 is an N-type high-concentration silicon substrate. The semiconductor layer 202 is an N-type low-concentration semiconductor layer deposited on the surface of the semiconductor substrate 201 by the epitaxial growth method.

The insulator mask pattern 203 is a mask pattern for etching that opens on the surface of the semiconductor layer 202 in the region where the trench is to be formed. An insulating material that constitutes the insulator mask pattern 203 includes silicon oxide, silicon nitride, TEOS (tetraethyl orthosilicate), or the like. The insulator mask pattern 203 is deposited using, for example, chemical vapor deposition (CVD).

Any number of trenches 204 can be formed.

Next, a process of forming a doping mask is performed to introduce a P-type impurity under the trench 204, followed by a process of doping.

In the process of forming the doping mask, first, an insulator layer 205 is formed as shown in FIG. 9. The insulator layer 205 is deposited on the insulator mask pattern 203 described in the above process of forming the trench. At the same time, the insulator layer 205 covers the bottom surface and lateral surface of the trench 204. An insulating material that constitutes the insulator layer 205 includes silicon oxide, silicon nitride, TEOS (tetraethyl orthosilicate), or the like. The insulator layer 205 is deposited using, for example, chemical vapor deposition (CVD).

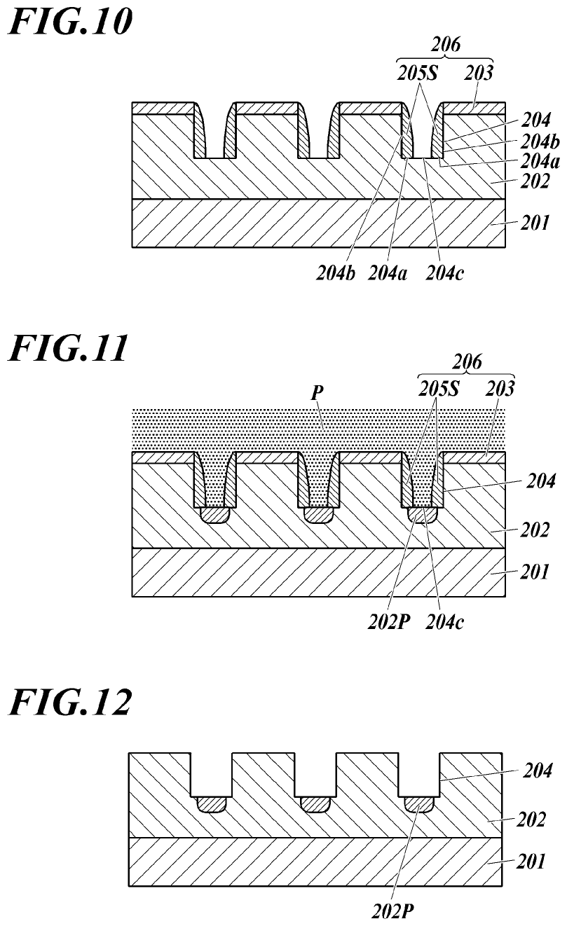

Next, as shown in FIG. 10, the entire surface is etched. The etching applied is anisotropic etching. As the anisotropic etching, a reactive etching method is applied in which the etching rate in the vertical direction, perpendicular to the surface, is larger than the etching rate in the horizontal direction, parallel to the surface.

Therefore, as shown in FIG. 10, it is possible to expose a middle portion 204c of the bottom surface of the trench 204 while a sidewall insulator 205S is left, which is a part of the insulator layer 205 and covers the outer edge portion 204a of the bottom surface and the lateral surface 204b of the trench 204. This is because the sidewall insulator 205S remains when the insulator on the middle portion 104c of the bottom surface of the trench 204 is removed by vertical etching.

The sidewall insulator 205S is thicker at a portion closer to the bottom surface of the trench 204 because the etching progresses more at the portion closer to the opening of the trench 204.

On the surface of the semiconductor layer 202 around the trench 204, the insulator mask pattern 103 is covered by the insulator layer 205 before etching as shown in FIG. 9. Therefore, when the insulator on the middle portion 204c of the bottom surface of the trench 204 is removed by vertical etching, the insulator mask pattern 203 also remains.

The insulator mask pattern 203 and the sidewall insulator 205S remaining after the above anisotropic etching are collectively referred to as an insulator mask pattern 206.

As shown in FIG. 10, the insulator mask pattern 206 covers the surface of the semiconductor layer 202 around the trench 204, the outer edge portion 204a of the bottom surface of the trench 204, and the lateral surface 204b of the trench 204, and is a pattern that exposes the middle portion 204c of the same bottom surface. This insulator mask pattern 206 is used as a mask for the subsequent doping process.

Next, the process of doping is performed.

In the process of doping, as shown in FIG. 11, an impurity of a second conductivity type (P-type in this embodiment) is introduced into the semiconductor layer 202 through the middle portion 204c of the bottom surface of the trench 204, using the insulator mask pattern 206 as a mask. A vapor diffusion method is applied as the method for introducing impurity. Since there is a sidewall insulator 205S in the trench 204, the surface through which the impurity P is introduced into the semiconductor layer 202 is limited to the middle portion 204c inside the sidewall insulator 205S.

After being introduced, the P-type impurity is activated by annealing to form a P-type region 202P. After this annealing, the P-type impurity diffuses in the semiconductor layer 202 more than at the time of introduction, but remains within the width of the trench 204 in the lateral direction, so that the P-type region 202P does not protrude outward from the trench 204.

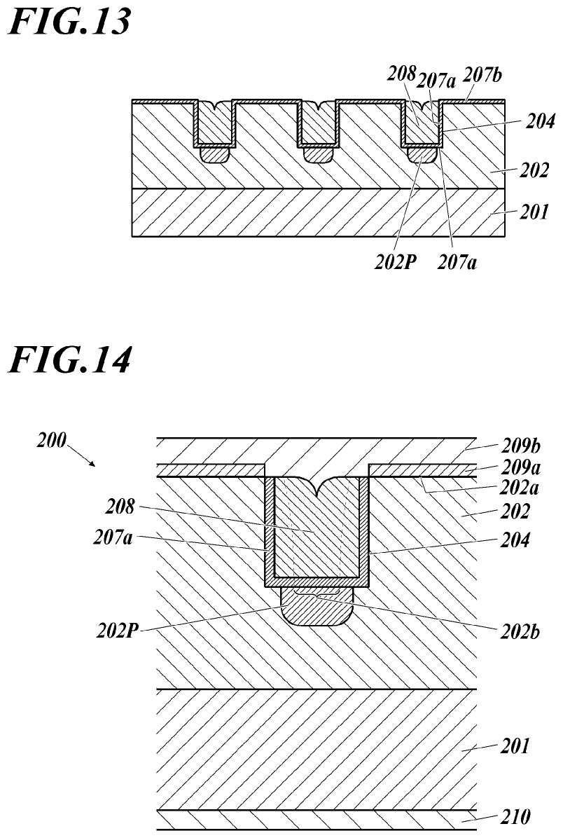

Next, the insulator mask pattern 206 is removed as shown in FIG. 12, insulating films (thermal oxide films) 207a and 207b are formed on the surface of the semiconductor layer 202 including inside the trench 204 as shown in FIG. 13, and then the trench 204 is filled with a conductive body 208. The material of the conductive body 208 may be polysilicon or a metal material.

Furthermore, after the insulating film 207b around the trench 204 is removed, as shown in FIG. 14, a Schottky metal film 209a is joined with the surface 202a of the semiconductor layer 202 to form a Schottky barrier, and then a surface electrode metal film 209b is further formed to connect the Schottky metal film 209a and the conductive body 208. Furthermore, a back electrode metal film 210 is formed.

### (Semiconductor Device)

The semiconductor device 200 shown in FIG. 14 that can be manufactured by the above manufacturing method, for example, includes: the semiconductor substrate 201 that has a first conductivity type at a relatively high concentration; the semiconductor layer 202 that is deposited on the surface of the semiconductor substrate 201 and has the first conductivity type at a relatively low concentration; the trench 204 formed on the surface of the semiconductor layer 202; the insulating film 207a that covers the bottom surface and the lateral surface of the trench 204; the conductive body 208 that fills the inside of the trench 204 covered by the insulating film 207a; the second conductive type region 202P that is formed in the semiconductor layer 202; and the Schottky metal film 209a that electrically connects to the conductive body 208 and forms a Schottky barrier with the surface 202a of the semiconductor layer 202.

The second conductive type region 202P is arranged under the trench 204 and is within the region of the trench 204 in a plan view of the semiconductor substrate 201.

More specifically, in a plan view of the semiconductor substrate 201, the second conductive type region 202P is not in contact with the outer edge of the region of the trench 204, but is separated from the outer edge by a certain distance to be within the region of the trench 204.

The second conductive type region 202P is within the width of the bottom portion of the trench 204, and does not cover the corner of the bottom portion of the trench 204. The corner of the bottom portion of the trench 204 may have a round shape. This effectively relaxes local concentration of the electric field when a reverse voltage is applied.

The region in the semiconductor layer 202 except the region of the trench 204 in the plan view of the semiconductor substrate 201 is occupied by the first conductive type (N-type) region. Therefore, it is possible to ensure a large conductive region for forward current under a Schottky junction.

The second conductive type region 202P is a region formed by the vapor diffusion. The impurity-introduced surface appearing at the bottom surface of the trench 204 corresponds to the middle portion 204c in FIG. 11. In a plan view of the semiconductor substrate 201, the middle portion 204c does not contact the outer edge of the region of the trench 204, but is inside the region of the trench 204. The impurity-introduced surface 202b appearing at the bottom surface of the trench 204 has a width narrower than the final diffusion width of the second conductive type region 202P in FIG. 14. The outline of the sidewall insulator 205S in FIG. 11 is also illustrated with dashed lines in FIG. 14. The inside of the line corresponds to the impurity-introduced surface 202b.

The impurity concentration distribution of the second conductivity type (P-type) in the second conductive type region 202P takes its highest value at the impurity-introduced surface 202b. This is due to the diffusion method from the surface.

The P-type impurity also diffuses laterally from the impurity-introduced surface 202b, but it is distributed at a lower concentration than at the impurity-introduced surface 202b.

The semiconductor device 200 can be applied to SBDs (Schottky diodes), MOSFETs (metal-oxide-semiconductor field-effect transistors), IGBTs (Insulated Gate Bipolar Transistors), and the like.

When the semiconductor device 200 constitutes a MOSFET, the P-body, gate, and the like are formed in the center portion, and the surface electrode metal film 209b serves as a source electrode and the back electrode metal film 210 serves as a drain electrode. When the semiconductor device 200 constitutes an IGBT, further, a p-type high-concentration substrate is applied as the semiconductor substrate 201, the surface electrode metal film 209b serves as an emitter electrode, and the back electrode metal film 210 serves as a collector electrode.

### Effects

According to the above-described embodiments, the second conductive type region arranged under the trench relaxes the electric field when a reverse voltage is applied so as to improve the voltage resistance. Furthermore, it is possible to ensure the conductive region for forward current under a Schottky junction so as to suppress the increase in the on-resistance.

### [Comparison of Characteristics]

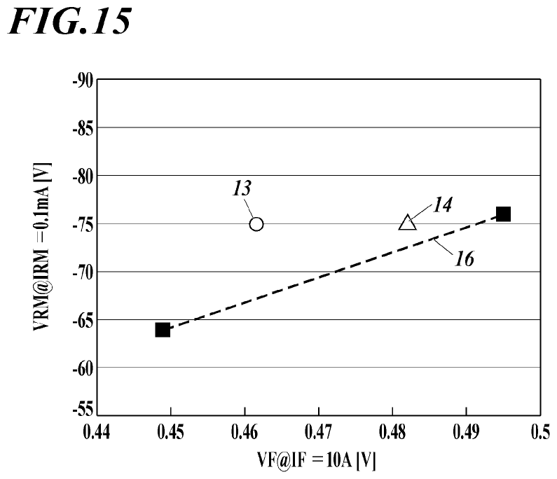

FIG. 15 shows VF-VRM characteristics for the examples of comparison and the present invention. VF is a forward voltage when the forward current IF=10 [A]. VRM is the voltage resistance and is a reverse voltage when the reverse leakage current IRM=0.1 [mA].

A point 13 in the graph of FIG. 15 indicates the characteristics of the SBD of an example of the present invention according to the above first embodiment. A point 14 in the graph of FIG. 15 indicates the characteristics of the SBD of a comparative example having a P-type region 102P protruding outward from the trench 104. The other conditions were common to those of the SBD of the example of the present invention (point 13).

A line 16 in the graph of FIG. 15 indicates the characteristics of the SBD of a comparative example having no P-type region 102P. The other conditions were common to those of the SBD of the example of the present invention (point 13). The line 16 indicates that, as the N-type impurity concentration in the semiconductor layer 102 is decreased, VF and VRM tend to increase linearly.

Among the SBDs of comparative examples in which the P-type region 102P protruded outward from the trench 104, the SBD indicated by point 14 had an improved voltage resistance VRM than a SBD of a comparative example having no P-type region 102P. However, the forward voltage VF increased in turn.

In the SBD of comparative examples having the P-type region 102P protruding outward from the trench 104, the forward voltage VF increases as the voltage resistance VRM is improved. This is because the improvement of voltage resistance is achieved, but is accompanied by an increase in on-resistance.

In contrast, in the SBD of the example of the present invention (point 13), the voltage resistance was improved while suppressing the increase in on-resistance. Thus, compared to the comparative examples, it was possible to achieve lower VF and higher voltage resistance VRM.

The embodiments of the present disclosure have been described above, but these embodiments are shown as examples and can be implemented in various other forms. Omission, replacement, or modification of components may be made as long as they do not depart from the gist of the invention.

### INDUSTRIAL APPLICABILITY

The present disclosure can be used for a semiconductor device and a method for manufacturing the semiconductor device.

### REFERENCE SIGNS LIST

100 Semiconductor Device
101 Semiconductor substrate
102 Semiconductor Layer (N-type)
102P Second Conductive Type Region (P-type)
104 Trench
107a Insulating Film (Thermal Oxide Film)
108 Conductive Body
109a Schottky Metal Film
109b Surface Electrode Metal Film
110 Back Electrode Metal Film

1. A semiconductor device comprising:
a semiconductor substrate;
a semiconductor layer of a first conductivity type that is deposited on a surface of the semiconductor substrate;
a trench that is formed on a surface of the semiconductor layer;
an insulating film that covers a bottom surface of the trench and a lateral surface of the trench;
a conductive body that fills inside the trench that is covered by the insulating film;
a second conductive type region that is formed in the semiconductor layer, is arranged under the trench, and is within a region of the trench in a plan view of the semiconductor substrate; and
a metal film that is electrically connected to the conductive body and forms a Schottky barrier with the surface of the semiconductor layer.

2. The semiconductor device according to claim 1, wherein the second conductive type region is within the region of the trench in the plan view without being in contact with an outer edge of the region of the trench in the plan view of the semiconductor substrate.

3. The semiconductor device according to claim 1, wherein a first conductivity type region occupies a region in the semiconductor layer except the region of the trench in the plan view of the semiconductor substrate.

4. The semiconductor device according to claim 1, wherein the second conductive type region is formed by ion implantation.

5. The semiconductor device according to claim 4, wherein an ion implanted surface that is on the bottom surface of the trench is within the region of the trench in the plan view without being in contact with an outer edge of the region of the trench in the plan view of the semiconductor substrate.

6. The semiconductor device according to claim 1, wherein an impurity concentration distribution of a second conductivity type in the second conductive type region takes a highest value at a depth separated from the bottom surface of the trench.

7. The semiconductor device according to claim 1, wherein the second semiconductor region has an impurity of a second conductivity type formed by vapor diffusion.

8. The semiconductor device according to claim 1, wherein the insulating film is a thermal oxide film.

9. A method for manufacturing a semiconductor device, comprising the semiconductor device including:
depositing a semiconductor layer of a first conductivity type on a surface of a semiconductor substrate;
forming a trench that on a surface of the semiconductor layer;
covering a bottom surface of the trench and a lateral surface of the trench with an insulating film;
filling a conductive body inside the trench that is covered by the insulating film;
forming a second conductive type region in the semiconductor layer and under the trench;
connecting a metal film to the conductive body to form a Schottky barrier with a surface of the semiconductor layer;
forming a doping mask that is an insulator mask pattern that exposes a middle portion of the bottom surface of the trench, and that covers a surface of the semiconductor layer around the trench, an outer edge portion of a bottom surface of the trench, and a lateral surface of the trench; and
doping an impurity of a second conductive type using the insulator mask pattern as a mask, including introducing the impurity in the semiconductor layer through the middle portion of the bottom surface.

10. The method for manufacturing a semiconductor device according to claim 9, further comprising:
forming the trench before the forming of the doping mask, including forming the insulator mask pattern that opens on the surface of the semiconductor layer in a region where the trench is to be formed, and etching the semiconductor layer using the insulator mask pattern as a mask,
forming an insulator layer in the forming of the doping mask, the insulator layer being deposited on the insulator mask pattern in the forming of the trench and covering a bottom surface and lateral surface of the trench, and
performing anisotropic etching of the insulator layer so as to expose the middle portion of the bottom surface of the trench while a part of the insulator layer remains, the part of the insulator layer covering an outer edge portion of the bottom surface of the trench and the lateral surface of the trench.
